(19) United States
(12) Patent Application Publication
(10) Pub. No.: US 2010/0297835 A1
(43) Pub. Date: Nov. 25, 2010

(54) METHODS FOR FABRICATING COPPER INDIUM GALLIUM DISELENIDE (CIGS) COMPOUND THIN FILMS

(75) Inventors: Chia-Chih Chuang, Miaoli County (TW); Jhe-Wei Guo, Yunlin County (TW); Yu Huang, Hsinchu (TW)

Correspondence Address: PAI PATENT & TRADEMARK LAW FIRM, 1001 FOURTH AVENUE, SUITE 3200, SEATTLE, WA, 98154, US

(73) Assignee: INDUSTRIAL TECHNOLOGY RESEARCH INSTITUTE, Hsinchu County (TW)

(21) Appl. No.: 12/567,762

(22) Filed: Sep. 26, 2009

(30) Foreign Application Priority Data
May 22, 2009 (TW) 098117037

(51) Int. Cl. H01L 21/20; H01L 31/18

(52) U.S. Cl. 438/488; 438/95; 257/E21.09; 257/E31.008

(57) ABSTRACT

A method for fabricating a copper-indium-gallium-diselenide (CIGS) compound thin film is provided. In this method, a substrate is first provided. An adhesive layer is formed over the substrate. A metal electrode layer is formed over the adhesive layer. A precursor stacked layer is formed over the metal electrode layer, wherein the precursor stacked layer includes a plurality of copper-gallium (CuGa) alloy layers and at least one copper-indium (CuIn) alloy layer sandwiched between the plurality of CuGa alloy layers. An annealing process is performed to convert the precursor stacked layer into a copper-indium-gallium (CuInGa) alloy layer. A selenization process is performed to convert the CuInGa alloy layer into a copper-indium-gallium-diselenide (CuInGaSe) compound thin film.

### CROSS REFERENCE TO RELATED APPLICATIONS

This Application claims priority of Taiwan Patent Application No. 98117037, filed on May 22, 2009, the entirety of which is incorporated by reference herein.

### BACKGROUND OF THE INVENTION

1. Field of the Invention

The present invention relates to fabrication of compound semiconductor thin films, and in particularly to methods for fabricating copper-indium-gallium-diselenide (CIGS) compound thin films

2. Description of the Related Art

A silicon solar cell is one type of solar cell. Fabrication of silicon solar cells, however, require large factories and much power consumption. Therefore, material costs and fabrication costs for forming silicon solar cells are high. Due to physical limitations of silicon, a thickness of the silicon solar cell is normally greater than 200 μm and a large amount of silicon material is needed for fabrication thereof.

Therefore, new solar cell fabrication techniques have been developed, such as thin film solar cells incorporating IB-IIIA-VIA₂ compound semiconductor materials such as copper-indium-gallium-diselenide (CIGS) material. The CIGS material with a chemical formula CuInGaSe₂ used in the thin film solar cells has characteristics such as a large light absorbing spectrum range and good reliability. By using CIGS compound semiconductor materials, thin film solar cells can be fabricated on a substrate of relatively cheaper material than silicon, such as glass, plastic or stainless steel. Thickness of the thin film solar cell can be reduced when compared with conventional silicon solar cells.

Fabrication of CIGS compound thin films is mainly achieved by first forming a plurality of precursor films including materials such as metal, alloy and compound materials over a substrate by a sputtering process, and a selenium reaction is then performed to process the plurality of precursor films formed over the substrate such that a CIGS compound thin film is formed.

Referring to FIGS. 1 and 2, a conventional method for fabricating a CIGS compound thin film is illustrated.

As shown in FIG. 1, a substrate 100 made of materials such as glass, metal foil and polymer is provided. A molybdenum (Mo) layer 102 of a thickness of about 500-1200 nm is then formed over the substrate 100. A copper-gallium (CuGa) alloy layer 104, an indium (In) layer 106 and another Cu—Ga alloy layer 108 are then sequentially formed over the Mo layer 102 by sputtering processes (not shown). The Cu—Ga alloy layer 104, the In layer 106 and the other Cu—Ga alloy layer 108 stacked over the Mo layer 102 function as a precursor layer 110 for fabrication of an CIGS compound thin film.

As shown in FIG. 2, an annealing process (not shown) and a selenization process 102 are then sequentially performed to thereby form a CIGS compound thin film 114 of chalcopyrite structure through alloying and selenization of the Cu—Ga alloy layer 104, the In layer 106 and the Cu—Ga alloy layer 108.

The CIGS compound thin film 114 formed by the precursor structure illustrated in FIGS. 1 and 2 has drawbacks such as uneven film roughness and poor film uniformity and thin film leveling. This is because the indium metal in the In layer 106 has a melting point of about 156.6° C., and a sputtering process for forming the indium metal in the In layer 106, however, is performed at a temperature of about 150˜250° C., which is higher than the melting point of the In layer 106. Therefore, during formation of the In layer 106 over the Cu—Ga alloy layer 104 by the sputtering process, the indium metal is formed at a melting status or near melting status, thereby forming stacks of In layer 106 indium grains over the Cu—Ga alloy layer 104, and the obtained In layer 106 is thus formed with an uneven surface and nonuniform thickness, as shown in FIG. 1. Since the In layer 106 has an uneven surface and nonuniform thickness, the topography of the film stack of the precursor structure 110 including the Cu—Ga alloy layer 104, the In film 106, and the Cu—Ga alloy layer 108 is also affected, and the CIGS compound thin film 114 sequentially formed after the selenization process 112 also shows a uneven topography. A CIGS compound thin film 114 with an uneven surface and nonuniform thickness may affect cell efficiency of a thin film solar cell, thereby reducing photovoltaic conversion efficiency of the thin film solar cell.

In addition, the structure shown in FIG. 2 also has the following issues. Delamination of the CIGS thin film 114 typically occurs during the selenization process 112 illustrated in FIG. 2 at an interface between the Mo layer 102 and the substrate 100. Delamination of the Mo layer 102 from the substrate 100 is due mainly to large thermal stress for the CIGS thin film 114 during the selenium reaction 112. Specifically, the thermal stress is due mainly to the differences of thermal expansion coefficient (CTE) between the materials such as glass, metal foil, and polymer used in the substrate 100 and the Mo layer 102. Due to the CTE differences between the substrate 100 and the Mo layer 102, therefore a great thermal stress caused by the differences of CTE is typically happened while a process temperature performed thereto is above 400° C. This is why delamination happed to the composite layer including the CIGS thin film 114, the Mo layer 102 and the substrate 100.

### BRIEF SUMMARY OF THE INVENTION

Accordingly, methods for fabricating copper-indium-gallium-diselenide (CIGS) thin films are provided to solve the above mentioned drawbacks.

An exemplary method for fabricating a copper-indium-gallium-diselenide (CIGS) thin film comprises providing a substrate. An adhesive layer is formed over the substrate. A metal electrode layer is formed over the adhesive layer. A precursor stacked layer is formed over the metal electrode layer, wherein the precursor stacked layer comprises a plurality of copper-gallium (CuGa) alloy layers and at least one copper-indium (CuIn) alloy layer sandwiched between the plurality of CuGa alloy layers. An annealing process is performed to convert the precursor stacked layer into a copper-indium-gallium (CuInGa) alloy layer. A selenization process is performed to convert the CuInGa alloy layer into a copper-indium-gallium-diselenide (CuInGaSe) compound thin film.

A detailed description is given in the following embodiments with reference to the accompanying drawings.

### BRIEF DESCRIPTION OF THE DRAWINGS

The invention can be more complete understood by reading the subsequent detailed description and examples with references made to the accompanying drawings, wherein:

FIGS. 1-2 are cross sections showing a conventional method for fabricating copper-indium-gallium-diselenide (CIGS) thin film;

FIGS. 3-5 are cross sections showing a method for fabricating copper-indium-gallium-diselenide (CIGS) thin film according to an embodiment of the invention;

FIGS. 6-7 are cross sections showing a method for fabricating copper-indium-gallium-diselenide (CIGS) thin film according to another embodiment of the invention;

FIG. 8 is a flowchart showing a method for fabricating copper-indium-gallium-diselenide (CIGS) thin film according to an embodiment of the invention; and

FIG. 9 is a spectrum diagram showing X-ray analysis results of a copper-indium-gallium-diselenide (CIGS) thin film obtained in an exemplary example of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

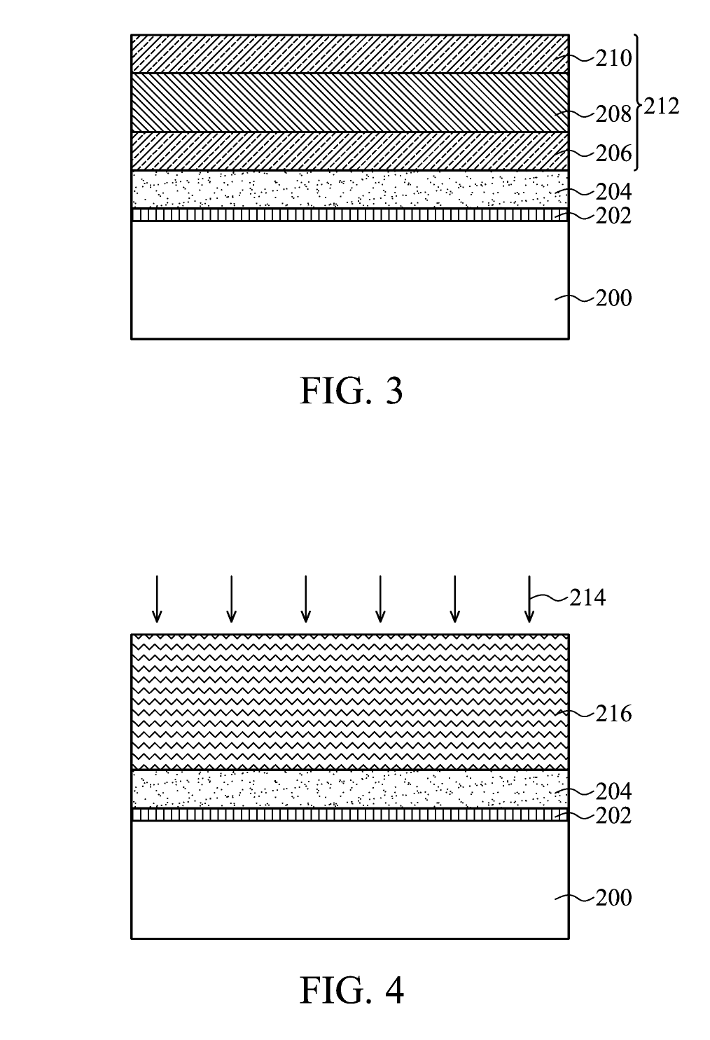

FIGS. 3-5 are cross sections showing an exemplary method for fabricating copper-indium-gallium-diselenide (CIGS) thin film.

As shown in FIG. 3, a substrate 200 made of materials such as glass, metal foil or polymer is provided. Herein, the substrate 200 is a previously cleaned substrate to remove containments such as sludge or microparticles left thereon. Next, an adhesive layer 202 and a metal electrode layer 204 are sequentially formed over the substrate 200. The adhesive layer 202 reduces differences of thermal expansion coefficient (CTE) between the metal electrode layer 204 and the substrate 200, such that adhesion between the metal electrode layer 204 and the substrate 200 is improved. In one embodiment, the adhesive layer 202 formed over the substrate 200 can be, for example, a molybdenum (Mo) layer formed by sputtering under a pressure of over 5 mtorr, and the metal electrode layer 204 can be, for example, a molybdenum (Mo) layer formed over the adhesive layer 202 by sputtering under a pressure less than 5 mtorr. In this embodiment, the molybdenum layer used as the adhesive layer 202 is preferably formed under a pressure of about 6-8 mtorr and is formed under the metal electrode layer 204. In one embodiment, the adhesive layer 202 is formed with a thickness of about 50˜600 nm, and the metal electrode layer 204 is formed with a thickness of about 200˜600 nm. The adhesive layer 202 and the metal electrode layer 204 have a composite thickness of not more than 1200 nm, for example, a thickness of about 1000 nm. In other embodiment, the adhesive layer 202 may be a metal layer formed of materials such as Ti, Ta, Co, Cr, Ni, W, or alloys thereof, to further reduce differences of thermal expansion coefficients (CTEs) between the metal electrode layer 204 and the substrate 200, and the metal electrode layer 204 can be a metal layer comprising molybdenum.

Next, a precursor stacked layer 212 is formed over a top surface of the metal electrode layer 204. The precursor stacked layer 212 comprises two separate copper-gallium (Cu—Ga) alloy layers 206, 210, and a copper-indium (Cu—In) alloy layer 208 sandwiched between the Cu—Ga alloy layers 206 and 210. Herein, the Cu—Ga alloy layers 206, 210, and the Cu—In alloy layer 208 can be formed over the metal electrode layer 204 by methods such as sputtering, an evaporation process, an electroplating process, or combinations thereof. In one embodiment, when the Cu—Ga alloy layers 206, 210, and the Cu—In alloy layer 208 in the precursor stacked layer 212 are formed by a sputtering process, sputtering targets made of materials such as Cu_{y}Ga_{1-y} and CuₓIn₁₋ₓ can be used. A gallium content in the target made of Cu_{y}Ga_{1-y} is less than 78 at % (where y is greater than 0.22) and a copper content in the target made of CuₓIn₁₋ₓ is greater than 4 at % to maintain a status the above targets and an alloy layer formed over the metal electrode layer 204 in a solid state during the sputtering process, thereby providing the alloy layer with an uniform thickness and an averaged distribution of each element in the precursor stacked layer 212. In this embodiment, the Cu—Ga alloy layers 206, 210 in the precursor stacked layer 212 formed by the sputtering process have a chemical formula Cu_{y}Ga_{1-y}, wherein y is between 0.22-0.9, and the Cu—In alloy layer 208 in the precursor stacked layer 212 formed by the sputtering process has a chemical formula of CuₓIn₁₋ₓ, wherein x is between 0.04-0.5. In another embodiment, the Cu—Ga alloy layers 206, 210 are formed with a thickness of about 100˜600 nm, and the Cu—In alloy layer 208 is formed with a thickness of about 200˜700 nm. Distribution and composition of the elements at different thicknesses in the precursor stacked layer 212 shown in FIG. 3 may be varied along a thickness direction and can be adjusted to form selenium-containing compound thin films of preferred stoichiometry.

In FIG. 4, an annealing process 214 is performed on the structure shown in FIG. 3 to convert the precursor stacked layer 212 (shown in FIG. 3) into a copper-indium-gallium (CIG) alloy layer 216. In one embodiment, the annealing process 214 is performed under a temperature of about 150° C.˜400° C. for 10-80 minutes. In another embodiment, the annealing process 214 is preferably performed under a temperature of 300° C. for 40 minutes. After the annealing process 214, the CIG alloy layer 216 is formed with an even top surface and a uniform film thickness. A copper content in the CIG alloy layer 216 is of about 0.69˜1.3 (ratio of Cu/In+Ga) and a gallium content in the CIG alloy layer 216 is of about 0.1˜0.5 (ratio of Ga/In+Ga) to thereby ensure quality of the sequentially formed copper-indium-gallium-diselenide (CIGS) thin film.

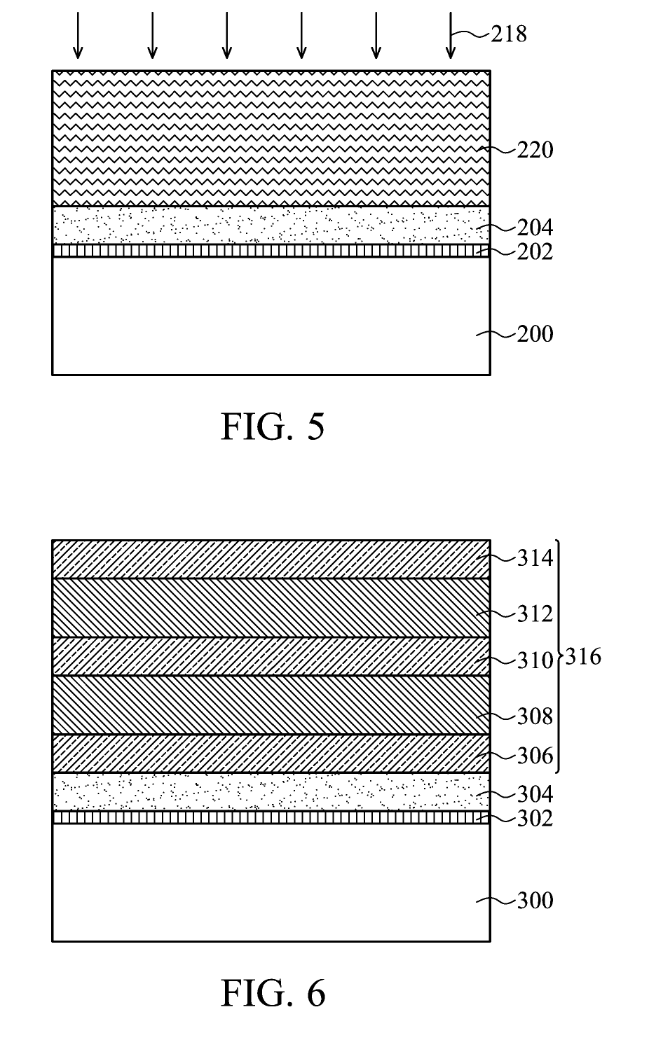

In FIG. 5, a selenization process 218 is performed on the structure shown in FIG. 4 to convert the CIG alloy layer 216 into a copper-indium-gallium-diselenide (CIGS) compound thin film 220. In one embodiment, the selenization process 218 is performed under a temperature of about 450˜600° C. and a pressure under 1*10⁻⁶ torr˜10 mtorr for about 10˜100 minutes. The copper-indium-gallium-diselenide (CIGS) thin film obtained after the selenization process 218 has an even top surface and a uniform film thickness. The above selenization process 218 may utilize selenium vapors or ionized selenium such as Se⁺ or Se⁺⁺ obtained by plasma decomposition to react with the CIG alloy layer 216 (shown in FIG. 4) to thereby form the copper-indium-gallium-diselenide (CIGS) compound thin film 220.

As shown in FIG. 5, the copper-indium-gallium-diselenide (CIGS) compound thin film 220 formed over the metal electrode 204 is formed with an even top surface and a uniform thickness. Herein, since the copper-indium-gallium-diselenide (CIGS) compound thin film 220 is formed with tetranary compound materials, the Ga and In elements therein may show a nonuniform concentration distribution along a thickness direction thereof. However, the Ga and In elements may show uniform concentration distribution along a surface direction of the copper-indium-gallium-diselenide (CIGS) compound thin film 220.

Therefore, since the copper-indium-gallium-diselenide (CIGS) compound thin film 220 illustrated in FIG. 5 has a uniform composition distribution along a top surface, a copper-indium-gallium-diselenide (CIGS) compound thin film of uniform thickness is obtained after the selenization process. In this embodiment, the Cu—Ga alloy layer, the In layer and the Cu—Ga alloy layer in the conventional precursor stacked film are replaced with the Cu—Ga alloy layer 206, the Cu—In alloy layer 208 and the Cu—Ga alloy layer 210, such that drawbacks of the precursor film due to the conventional sputtering process are solved and efficiency of a compound thin film solar cell using the alloy layers of the invention is improved.

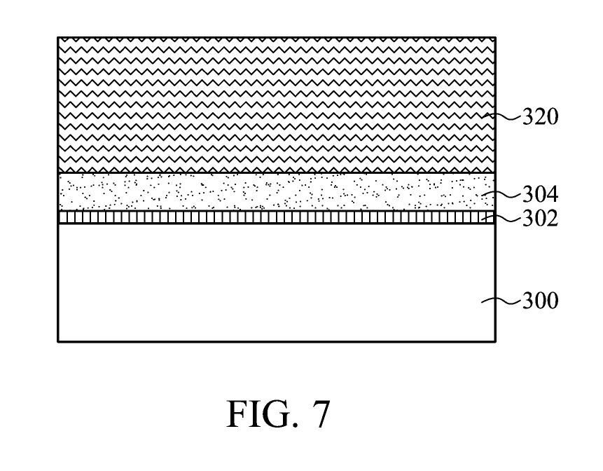

FIGS. 6-7 are cross sections showing another exemplary method for fabricating copper-indium-gallium-diselenide (CIGS) thin film modified from the exemplary method illustrated in FIGS. 3-5. Only differences between these exemplary methods are discussed as follows.

In FIG. 6, a substrate 300 is first provided, and an adhesive layer 302 and a metal electrode layer 304 are sequentially formed over the substrate 300. Next, a precursor stacked layer 316 is formed over the metal electrode layer 304. The precursor stacked layer 316 comprises three separate copper-gallium (Cu—Ga) alloy layers 306, 310, and 314, and two separate copper-indium (Cu—In) alloy layers 308 and 312 sandwiched between the Cu—Ga alloy layers 306, 310, and 314.

In FIG. 7, an annealing process and a selenization process (both not shown) are sequentially performed on the structure illustrated in FIG. 6 to form a copper-indium-gallium-diselenide (CIGS) compound thin film 320.

In this embodiment, the substrate 300, the adhesive layer 302, and the metal electrode 304 are the same with the substrate 200, the adhesive layer 202, and the metal electrode layer 204 described in the previous exemplary method. In addition, two Cu—Ga alloy layers and one Cu—In alloy layer are additionally provided in the precursor stacked layer 316 when compared with the precursor stacked layer 212 in the previous exemplary method. Characteristics and fabrication of the Cu—Ga alloy layers 306, 310 and 314, and the Cu—In alloy layers 308 and 312 are the same with the Cu—Ga alloy layers 206 and 210, and the Cu—In alloy layer 208 and are not described here again, for simplicity.

As shown in FIG. 7, the copper-indium-gallium-diselenide (CIGS) compound thin film 320 formed over the metal electrode 304 is formed with an even top surface and a uniform film thickness. Herein, since the copper-indium-gallium-diselenide (CIGS) thin film 320 is formed with tetranary compound materials, the Ga and In elements therein may have a nonuniform concentration distribution along a thickness direction thereof. However, the Ga and In elements may show uniform concentration distribution along a surface direction of the copper-indium-gallium-diselenide (CIGS) compound thin film 320. Therefore, since the copper-indium-gallium-diselenide (CIGS) compound thin film 320 illustrated in FIG. 7 has a uniform composition distribution along a top surface thereof, a copper-indium-gallium-diselenide (CIGS) compound thin film of uniform thickness is obtained after the selenization process. In this embodiment, the Cu—Ga alloy layer, the In layer and the Cu—Ga alloy layer in the conventional precursor stacked film are replaced with the three Cu—Ga alloy layers 306, 310, and 314, and the Cu—In alloy layers 308 and 312 sandwiched therebetween, such that drawbacks of the precursor film due to the conventional sputtering process are solved and efficiency of a compound thin film solar cell using the alloy layers of the invention is improved.

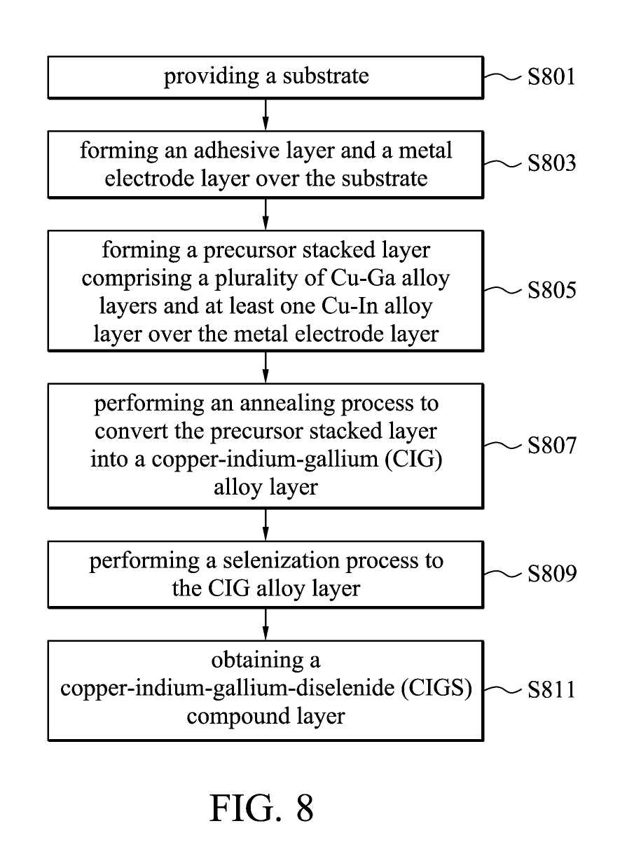

FIG. 8 is a schematic flowchart showing fabrication of a copper-indium-gallium-diselenide (CIGS) thin film as disclosed in FIGS. 3-5 and in FIGS. 6-7.

In FIG. 8, in step S801, a substrate is provided. The substrate is previously treated by a cleaning process to remove sludge and microparticles formed thereover. The cleaning process used is mainly wet cleaning processes incorporating detergents and ultrasonic vibrations to improve cleaning performance, and a dry process is performed in the last stage of the cleaning process. Next, in step S803, the cleaned substrate is placed in the deposition chamber and an adhesive layer and a metal electrode layer are then formed over the cleaned substrate by methods such as sputtering, evaporation, electroplating, or combinations thereof, thereby forming the adhesive layer and the metal electrode layer. Next, in step 805, a precursor stacked layer is formed over the metal electrode layer by methods such as sputtering, an evaporation process, an electroplating process, or combinations thereof. The precursor stacked layer comprises a plurality of Cu—Ga alloy layers and at least one Cu—In alloy layer sandwiched between the plurality of Cu—Ga alloy layers. The precursor stacked layer is formed with an even top surface and a uniform film thickness. Next, in step S807, an annealing process is performed to convert the precursor stacked layer comprising the plurality of Cu—Ga alloy layers and the at least one Cu—In alloy layer into a copper-indium-gallium (CIG) alloy layer. Next, in step S809, a selenization process is performed to convert the CIG alloy layer into a copper-indium-gallium-diselenide (CIGS) compound layer, as shown in step S811.

### EXAMPLES

### Example 1

A glass substrate was cleaned by immersion into a glass detergent and an ultrasonic vibrator was used to enhance glass cleaning performance. The cleaned glass substrate was then immersed in (deionized water) DI water and rinsed with DI water until no glass detergent was left. Next, the glass substrate was placed into an oven at a temperature of 150° C. to dry out the glass substrate. The cleaned glass substrate was instantly placed into a sputtering tool vacuum chamber and a pressure in the vacuum chamber was reduced to below 1*10⁻⁶ torr by a vacuum pump. When the pressure in the vacuum chamber achieved a high pressure, an argon flow was transported to the vacuum chamber at a flow rate of 10 sccm to recover the pressure in the vacuum chamber to 10 mtorr. At this time, a DC sputtering process was performed under the pressure of 10 mtorr to form a first Mo thin film with a thickness of about 400 nm. The first Mo thin film had good adhesion to the glass substrate, thereby serving as an adhesive layer. The first Mo thin film also had poor sheet resistance conductivity of over 1 ohms/square. Next, the pressure in the vacuum chamber was reduced to about 2 mtorr and a DC sputtering process was performed to form a second Mo thin film over the first Mo thin film. The second Mo thin film was formed with a thickness of about 600 nm, and had a poor adhesion to the glass substrate such that it did not server as a adhesive layer. Note that physical characteristics of the first and second Mo thin films can be adjusted by verifying oxygen contents in the sputtered Mo thin film by varying the sputtering pressure. Thus, an Mo thin film having higher oxygen content and good adhesion can be obtained under high sputtering pressure, and an Mo thin film with lower oxygen content can be formed under low sputtering pressure. Additionally, good sheet resistance of less than 0.2 ohms/squares can be achieved. The fabricated composite structure of the first and second Mo thin films and the glass substrate was left in the sputtering chamber, and a stacked film comprising Cu_{y}Ga_{1-y}/CuₓIn₁₋ₓ/Cu_{y}Ga_{1-y}/CuₓIn₁₋ₓ/Cu_{y}Ga_{1-y} composite structure shown in FIG. 6 was formed by a DC sputtering process. Alloy targets of Cu_{0.73}Ga_{0.27} and Cu_{0.48}In_{0.52} were used as precursor materials, and a Cu_{0.73}Ga_{0.27} alloy thin film with a thickness of 100 nm was sputtered over the composite structure comprising the first and second Mo thin films and the glass substrate structure with a power of 160 W. A Cu_{0.48}Ga_{0.52} alloy thin film with a thickness of 400 nm was then sputtered over the Cu_{0.73}Ga_{0.27} alloy thin film under reduced power of 60 W. Next, another Cu_{0.73}Ga_{0.27} alloy thin film with a thickness of 100 nm was again sputtered over the Cu_{0.48}Ga_{0.52} alloy thin film with a power of 160 W, and another Cu_{0.48}Ga_{0.52} alloy thin film with a thickness of 400 nm was again sputtered over the Cu_{0.73}Ga_{0.27} alloy thin film with a power of 60 W. At last, yet another Cu_{0.73}Ga_{0.27} alloy thin film with a thickness of 150 nm was then sputtered to form a precursor stacked layer for fabricating the CIGS compound layer made of five interlaced Cu_{0.73}Ga_{0.27} alloy thin films and Cu_{0.48}Ga_{0.52} alloy thin films. The precursor stacked layer of the five interlaced Cu_{0.73}Ga_{0.27} alloy thin films and Cu_{0.48}Ga_{0.52} alloy thin films showed a uniform thickness, having a overall thickness of about 1150 nm. Next, the precursor stacked layer of five interlaced Cu_{0.73}Ga_{0.27} alloy thin films and Cu_{0.48}Ga_{0.52} alloy thin films was taken out of the vacuum chamber and then placed into a selenization processing chamber, and an argon flow of a flow rate 150 cc/min was transported to the selenization processing chamber to protect the precursor stacked layer of five interlaced Cu_{0.73}Ga_{0.27} alloy thin films and Cu_{0.48}Ga_{0.52} alloy thin films from being oxided. The precursor stacked layer of five interlaced Cu_{0.73}Ga_{0.27} alloy thin films and Cu_{0.48}Ga_{0.52} alloy thin films was heated to 400° C. at a speed under 40° C./min and the precursor stacked layer of five interlaced Cu_{0.73}Ga_{0.27} alloy thin films and Cu_{0.48}Ga_{0.52} alloy thin films was hold at the temperature of 400° C. for 60 minutes to convert the precursor stacked layer into a CIG alloy layer. The temperature in the selenization processing chamber was then elevated to 550° C. under a speed in 15° C./min and the CIG alloy layer is hold at the temperature of 550° C. for 60 minutes. During the temperature elevation processes, selenium vapors were generated and provided in the selenization reacting chamber and the selenium vapors therein was maintained over a saturated vapor pressure to thereby perform selenization reaction with the CIG alloy layer. Thus, the CIG alloy layer was converted into a CIGS compound thin film. The obtained CIGS compound layer was then cooled in the selenization reacting chamber and fabrication of the CIGS compound thin film was completed.

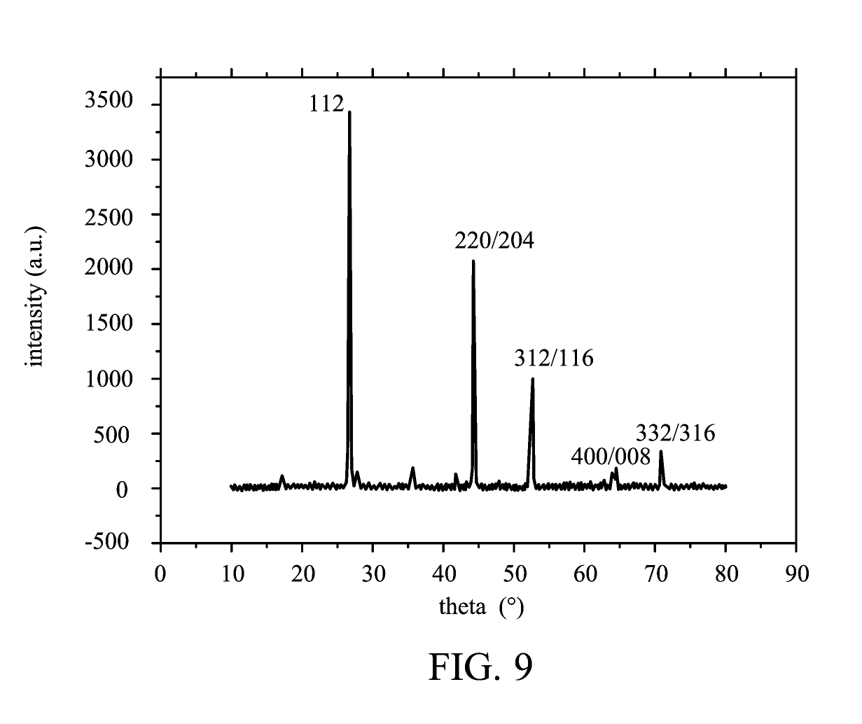

Next, the obtained CIGS compound thin film was examined by X-ray diffractometer (XRD) analysis and a spectrum pattern and related element analysis results were obtained, as shown in FIG. 9. In FIG. 9, the obtained CIGS compound thin film showed high crystallinity belonging to a polycrystalline structure, having crystalline planes of (112), (220/204), (312/116), (400/008) and (332/316). Thus a CuIn₁₋ₓGaₓSe₂ thin film having a preferred crystalline plane (112) was formed. Therefore, a CIGS compound thin film was obtained by performing a selenozation process on a precursor stacked layer comprising Cu_{0.48}In_{0.52}/Cu_{0.73}Ga_{0.27} sublayers, and the CIGS thin film was formed with polycrystalline planes. Due to high crystallinity, the CIGS compound thin film of the inventions is applicable as an absorber of a CIGS compound thin film solar cell.

### Example 2

A glass substrate was cleaned by immersion into a glass detergent and an ultrasonic vibrator was used to enhance glass cleaning performance. The cleaned glass substrate was then immersed in (deionized water) DI water and rinsed with DI water until no glass detergent was left. Next, the glass substrate was placed into an oven at a temperature of 150° C. to dry out the glass substrate. The cleaned glass substrate was instantly placed into a sputtering tool vacuum chamber and a pressure in the vacuum chamber was reduced to below 1*10⁻⁶ torr by a vacuum pump. When the pressure in the vacuum chamber achieved a high pressure, an argon flow was transported to the vacuum chamber at a flow rate of 10 sccm to recover the pressure in the vacuum chamber to 2 mtorr. At this time, a DC sputtering process was performed under the pressure of 10 mtorr to form a titanium (Ti) thin film with a thickness of about 100 nm. The Ti thin film showed good adhesion to the glass substrate, thereby serving as an adhesive layer. Next, the pressure in the vacuum chamber was kept at 2 mtorr and a DC sputtering process was performed to form an Mo thin film over the Ti thin film. The Mo thin film was formed with a thickness of about 800 nm, and had a sheet resistance below 0.2 ohms/square. The Mo layer and a stacked structure of Cu_{y}Ga_{1-y}/CuₓIn₁₋ₓ/Cu_{y}Ga_{1-y} were sequentially formed. The fabrication method used to form the Ti thin film was by a sputtering method. Thus, the Ti thin film was preferably formed with a thickness over 50 nm to maintain adhesion stability between thereof and the glass substrate. A preferably thickness in this example was 100 nm. In addition to the Ti thin film, a metal thin film made of Ta, Cr, Co, Ni, W, or combinations thereof can also be used as an adhesive layer formed between the Mo electrode and the glass substrate. The fabricated composite structure of the Ti thin film, the Mo thin film, and the glass substrate was left in the sputtering chamber, and a stacked film comprising Cu_{y}Ga_{1-y}/CuₓIn₁₋ₓ/Cu_{y}Ga_{1-y}/CuₓIn₁₋ₓ/Cu_{y}Ga_{1-y} composite structure shown in FIG. 6 was formed by a DC sputtering process. Alloy targets of Cu_{0.73}Ga_{0.27} and Cu_{0.48}In_{0.52} were used as precursor materials, and a Cu_{0.73}Ga_{0.27} alloy thin film with a thickness of 100 nm was sputtered over the composite structure comprising the Ti thin film, the Mo thin film and the glass substrate at a power of 160 W. Next, a Cu_{0.48}Ga_{0.52} alloy thin film with a thickness of 400 nm was then sputtered over the Cu_{0.73}Ga_{0.27} alloy thin film under a reduced power of 60 W. Next, another Cu_{0.73}Ga_{0.27} alloy thin film with a thickness of 100 nm was again sputtered over the Cu_{0.48}Ga_{0.52} alloy thin film, and another Cu_{0.48}Ga_{0.52} alloy thin film with a thickness of 400 nm was again sputtered over the Cu_{0.73}Ga_{0.27} alloy thin film. At last, yet another Cu_{0.73}Ga_{0.27} alloy thin film with a thickness of 150 nm was then sputtered to form a precursor stacked layer for fabricating the CIGS compound layer made of five interlaced Cu_{0.73}Ga_{0.27} alloy thin films and Cu_{0.48}Ga_{0.52} alloy thin films. The precursor stacked layer of five interlaced Cu_{0.73}Ga_{0.27} alloy thin films and Cu_{0.48}Ga_{0.52} alloy thin films showed a uniform thickness, having an overall thickness of about 1150 nm. Next, the precursor stacked layer of five interlaced Cu_{0.73}Ga_{0.27} alloy thin films and Cu_{0.48}Ga_{0.52} alloy thin films was taken out of the vacuum chamber and then placed into a selenization processing chamber, and an argon flow of a flow rate 150 cc/min was transported to the selenization processing chamber to protect the precursor stacked layer of five interlaced Cu_{0.73}Ga_{0.27} alloy thin films and Cu_{0.48}Ga_{0.52} alloy thin films from being oxided, and the precursor stacked layer of five interlaced Cu_{0.73}Ga_{0.27} alloy thin films and Cu_{0.48}Ga_{0.52} alloy thin films was heated to 350° C. at a speed under 40° C./min. Once the temperature 350° C. was achieved, the precursor stacked layer of five interlaced Cu_{0.73}Ga_{0.27} alloy thin films and Cu_{0.48}Ga_{0.52} alloy thin films was annealed for 60 minutes to convert the precursor stacked layer into a CIG alloy layer. A temperature in the selenization processing chamber was then elevated to 550° C. at a speed under 15° C./min and maintained at that temperature for 60 minutes. During the temperature elevations, selenium vapors were generated and provided in the selenization reacting chamber and the selenium vapors therein was maintained over a saturated vapor pressure to thereby perform a selenization reaction with the CIG alloy layer. Thus, the CIG alloy layer was converted into a CIGS compound thin film. The obtained CIGS compound layer was then cooled in the selenization reacting chamber and fabrication of the CIGS compound thin film was completed.

### Example 3

A glass substrate with an adhesive layer formed thereon was provided. An Mo thin film was formed over the adhesive layer by sputtering method. The Mo thin film was formed with a thickness of about 600 nm and the adhesive layer was the first Mo thin film used in Example 1, or a metal thin film made of Ti, Ta, Cr, Co, Ni, W, or combinations thereof. Next, a stacked film comprising Cu_{0.73}Ga_{0.27}/Cu_{0.48}In_{0.52}/Cu_{0.73}Ga_{0.27} composite structure shown in FIG. 3 was formed over the Mo thin film by a DC sputtering process. Alloy targets of Cu_{0.73}Ga_{0.27} and Cu_{0.48}In_{0.52} were used as precursor materials, and a Cu_{0.73}Ga_{0.27} alloy thin film with a thickness of 100 nm was sputtered over the composite structure comprising the Mo thin film and the glass substrate at a power of 160 W, and a Cu_{0.48}Ga_{0.52} alloy thin film with a thickness of 600 nm was then sputtered over the Cu_{0.73}Ga_{0.27} alloy thin film under a reduced power of 60 W. Next, another Cu_{0.73}Ga_{0.27} alloy thin film with a thickness of 200 nm was again sputtered over the Cu_{0.48}Ga_{0.52} alloy thin film. The precursor stacked layer was formed with three interlaced Cu_{0.73}Ga_{0.27} alloy thin films and Cu_{0.48}Ga_{0.52} alloy thin film, wherein the Cu_{0.73}Ga_{0.27} alloy thin films were formed with a thickness of 300 nm and the Cu_{0.48}Ga_{0.52} alloy thin film was formed with a thickness of 600 nm. Next, the precursor stacked layer of three interlaced Cu_{0.73}Ga_{0.27} alloy thin films and Cu_{0.48}Ga_{0.52} alloy thin film then placed into a selenization processing chamber. A pressure in the selenization processing chamber was reduced to 1*10⁻⁶ torr by a vacuum pump and the precursor stacked layer of three interlaced Cu_{0.73}Ga_{0.27} alloy thin films and Cu_{0.48}Ga_{0.52} alloy thin film was simultaneously heated to a temperature of 300° C. at a speed under 20° C./min. Once the temperature of 300° C. was achieved, the precursor stacked layer of three interlaced Cu_{0.73}Ga_{0.27} alloy thin films and Cu_{0.48}Ga_{0.52} alloy thin film was annealed for 30 minutes to convert the precursor stacked layer into a CIG alloy layer. A temperature in the selenization processing chamber was then elevated to 520° C. at a speed under 25° C./min. During the temperature elevation, an argon flow of 5 sccm was used as a carrier gas to transport selenium vapors into the selenization reacting chamber. The selenium vapors passed through a plasma region and were decomposed into ionized selenium atoms prior to entering the selenization processing chamber. The ionized selenium atoms diffused into the CIG alloy layer from a top surface thereof in a short time and reacted therewith to form a CIGS compound thin film at a temperature of 520° C. for 60 minutes. The CIGS compound thin film obtained in this example had high crystallinity and was formed with a chalcopyrite structure. A CIGS compound structure was formed while a temperature of the selenization processing was above 480° C. In this example, a temperature of the selenization processing should be above 520° C. and a reaction time of the selenization processing should be more than 60 minutes to ensure complete selenization of the CIG alloy layer. In this example, a surface of about 150 Ra of the precursor stacked layer of three interlaced Cu_{0.73}Ga_{0.27} alloy thin films and Cu_{0.48}Ga_{0.52} alloy thin film was obtained and examined by a scanning electron microscope (SEM).

### Comparative Example 1

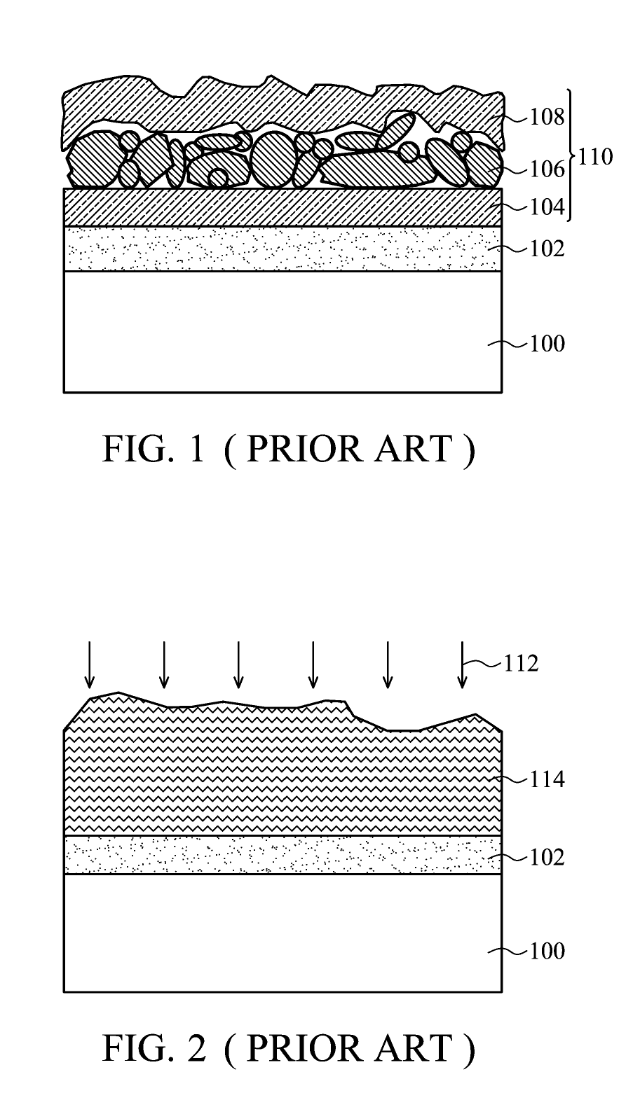

A precleaned glass substrate was provided and an Mo thin film with a thickness of about 1000 nm was formed over the glass substrate by a sputtering process. Next, a stacked film comprising the CuGa/In/CuGa composite structure shown in FIG. 1 was formed over the Mo thin film by a DC sputtering process. In this example, alloy targets of Cu, Ga and In were used as precursor materials, and a Cu_{0.73}Ga_{0.27} alloy thin film with a thickness of 100 nm was sputtered over the composite structure comprising the Mo thin film and the glass substrate structure with a power of 160 W, and an In thin film with a thickness of 600 nm was then sputtered over the Cu_{0.73}Ga_{0.27} alloy thin film under a reduced power of 60 W. Next, another Cu_{0.73}Ga_{0.27} alloy thin film with a thickness of 300 nm was again sputtered over the In thin film to form a precursor stacked layer for fabricating the CIGS compound layer made of a Cu_{0.73}Ga_{0.27} alloy thin film with a thickness of about 400 nm and an In thin film with a thickness of about 500 nm. The precursor stacked layer of three interlaced Cu_{0.73}Ga_{0.27} alloy thin films and the In thin film was then placed into a selenization processing chamber. A pressure in the selenization processing chamber was reduced to 1*10⁻⁶ torr by a vacuum pump and the precursor stacked layer of three interlaced Cu_{0.73}Ga_{0.27} alloy thin films and the In thin film was simultaneously heated to a temperature of 300° C. at a speed under 20° C./min. Once the temperature of 300° C. was achieved, the precursor stacked layer of three interlaced Cu_{0.73}Ga_{0.27} alloy thin films and the In thin film was annealed for 30 minutes to convert the precursor stacked layer into a CIG alloy layer. A temperature in the selenization processing chamber was then elevated to 550° C. at a speed under 15° C./min and the temperature in the selenization processing chamber was processed at 550° C. for 60 minutes. During the temperature elevation, selenium vapors were generated and provided in the selenization reacting chamber and the selenium vapors therein was maintained over a saturated vapor pressure to thereby perform selenization reaction with the CIG alloy layer. Thus, the CIG alloy layer was converted into a CIGS compound thin film. The obtained CIGS compound layer was then cooled in the selenization reacting chamber and fabrication of the CIGS compound thin film was completed.

In this comparative example, a surface of about 700 Ra of the precursor stacked layer of three interlaced Cu_{0.73}Ga_{0.27} alloy thin films and the In thin film was obtained and examined by a scanning electron microscope (SEM).

When comparing the surface roughness of the precursor stacked layers obtained in the Example 3 and the comparative Example 1, it is noted that a precursor stacked layer for the fabricating CIGS compound layer of the invention can be formed with a surface roughness not more than 200 Ra. Therefore, a surface roughness of the formed CIGS compound layer can be improved and cell efficiency and photovoltaic conversion efficiency of a thin film solar cell using the CIGS compound layer of the invention can also be improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a copper-indium-gallium-diselenide (CIGS) compound thin film, comprising:
providing a substrate;
forming an adhesive layer over the substrate;
forming a metal electrode layer over the adhesive layer;
forming a precursor stacked layer over the metal electrode layer, wherein the precursor stacked layer comprises a plurality of copper-gallium (CuGa) alloy layers and at least one copper-indium (CuIn) alloy layer sandwiched between the plurality of CuGa alloy layers;
performing an annealing process, converting the precursor stacked layer into a copper-indium-gallium (CuInGa) alloy layer; and
performing a selenization process, converting the CuInGa alloy layer into a copper-indium-gallium-diselenide (CuInGaSe) compound thin film.

2. The method as claimed in claim 1, wherein forming the adhesive layer comprises forming a molybdenum (Mo) layer.

3. The method as claimed in claim 1, wherein forming the adhesive layer comprising forming a molybdenum (Mo) layer under a pressure between 6˜12 mtorr.

4. The method as claimed in claim 1, wherein forming the adhesive layer comprising forming a metal layer comprising Ti, Ta, Co, Cr, Ni, W, or alloy thereof.

5. The method as claimed in claim 1, wherein the adhesive layer is formed with a thickness of about 50-600 nm.

6. The method as claimed in claim 1, wherein the adhesive layer and the metal electrode layer are formed of a composite thickness of not more than 1200 nm.

7. The method as claimed in claim 1, wherein the CuGa alloy layer in the precursor stacked layer is formed with a chemical formula Cu_{y}Ga_{1-y}, and y is between 0.22˜0.9.

8. The method as claimed in claim 1, wherein the at least one CuIn alloy layer in the precursor stacked layer is formed with a chemical formula CuₓIn₁₋ₓ, and x is between 0.04˜0.5.

9. The method as claimed in claim 1, wherein a copper content in the CuInGa alloy layer is about 0.6˜1.3 at %.

10. The method as claimed in claim 1, wherein a gallium content in the CuInGa alloy layer is about 0.1˜0.5 at %.

11. The method as claimed in claim 1, wherein the selenization process is performed under a temperature above 450° C.

12. The method as claimed in claim 1, wherein the selenization process is performed for 10-100 minutes.

13. The method as claimed in claim 1, wherein the plurality of CuGa alloy layers and the at least one CuIn alloy layer in the precursor stacked layer over the metal electrode layer are formed by a sputtering process, an evaporation process, an electroplating process, or combinations thereof.

14. The method as claimed in claim 1, wherein the CIGS thin film has surface roughness of not more than 200 Ra.

15. The method as claimed in claim 1, wherein the selenization process is performed by reacting ionized selenium atoms with the CuInGa alloy layer to thereby form the CuInGaSe compound thin film.

16. The method as claimed in claim 15, wherein the ionized selenium atoms are selenium atoms decomposed by plasma.

17. The method as claimed in claim 15, wherein the selenization process is performed under a temperature of about 450-600° C.

18. The method as claimed in claim 15, wherein the selenization process is performed under a pressure of about 1*10⁻⁶ ton to 10 mtorr.

19. The method as claimed in claim 1, wherein the annealing process is performed under a temperature of about 150-400° C.

20. The method as claimed in claim 1, wherein the annealing is performed for about 10-80 minutes.

21. The method as claimed in claim 1, wherein the substrate is a substrate processed by wet cleaning.

22. The method as claimed in claim 1, wherein the metal electrode layer comprises molybdenum.
